(19) United States
(12) Patent Application Publication
(10) Pub. No.: US 2024/0188303 A1
(43) Pub. Date: Jun. 6, 2024

(54) ULTRAHIGH TUNNELING ELECTRORESISTANCE IN FERROELECTRIC TUNNELING JUNCTION WITH GIANT BARRIER HEIGHT MODULATION BY MONOLAYER GRAPHENE CONTACT

(71) Applicant: UNIVERSITY OF SOUTHERN CALIFORNIA, Los Angeles, CA (US)

(72) Inventors: Han Wang, Los Angeles, CA (US); Jiang-Bin Wu, Los Angeles, CA (US); Hung-Yu Chen, Los Angeles, CA (US)

(73) Assignee: UNIVERSITY OF SOUTHERN CALIFORNIA, Los Angeles, CA (US)

(21) Appl. No.: 18/562,729

(22) PCT Filed: Jun. 22, 2022
(86) PCT No.: PCT/US22/34548

§ 371 Date: Nov. 20, 2023

Related U.S. Application Data
(60) Provisional application No. 63/213,296, filed on Jun. 22, 2021.

(51) Int. Cl. H10B 53/00

(52) U.S. Cl. CPC H10B 53/00; H01L 28/40

(57) ABSTRACT

An apparatus for novel high-speed low power non-volatile memory for the next generation electronic memory and computing technology is provided. The apparatus may include a ferroelectric tunnel junction (FTJ) that can switch between two or more conductance states in a reversible and non-volatile manner. A ferroelectric tunnel junction (FTJ) having two electrodes separated by a thin ferroelectric (FE) insulating layer has potential to replace existing volatile and non-volatile memory. Through the application of electrical pulses, the electrical resistance of an FTJ can be reversibly changed in a non-volatile manner by switching the ferroelectric polarization in the ferroelectric insulator layer.

### CROSS-REFERENCE TO RELATED APPLICATIONS

This application is based upon and claims priority to U.S. provisional patent application 63/213,296 entitled “ULTRAHIGH TUNNELLING ELECTRORESISTANCE IN FERROELECTRIC TUNNELLING JUNCTION WITH GIANT BARRIER HEIGHT MODULATION BY MONOLAYER GRAPHENE CONTACT” and filed on Jun. 22, 2021, the entire content of which is incorporated herein by reference.

### STATEMENT AS TO FEDERALLY SPONSORED RESEARCH

This invention was made with United States government support under Contract No. CCF-1618038 awarded by the National Science Foundation (NSF) and under Contract No. W911NF-18-1-0268 awarded by the U.S. Army Research Office (ARO). The United States government has certain rights in this invention.

### BACKGROUND

### 1. Field

This disclosure relates generally to ferroelectric tunnelling junctions, and more specifically, to ultrahigh tunnelling electroresistance in ferroelectric tunnelling junctions with barrier height modulation.

### 2. Description of the Related Art

Ferroelectric tunnel junctions use a thin ferroelectric layer as a tunnelling barrier, the height of which can be modified by switching its ferroelectric polarization. The junctions can offer low power consumption, non-volatile switching and non-destructive readout, and thus are promising for the development of memory and computing applications. However, achieving a high tunnelling electroresistance (TER) in these devices remains challenging. Typical junctions, such as those based on barium titanate or hafnium dioxide, are limited by their small barrier height modulation of around 0.1 eV. Thus, there remains a need for ferroelectric tunnel junctions that achieve high tunnelling electroresistance.

### SUMMARY

A device includes a first contact and a second contact. The first contact may be made of a semi-metallic material, such as graphene. The graphene may be monolayer graphene. The second contact may be made of a metal material, such as chromium (Cr). Thus, the first contact and the second contact may form asymmetric electrodes. A ferroelectric insulating layer is disposed between the first contact and the second contact and is electrically connected to the first contact and to the second contact. The asymmetric electrodes may cause a large modulation of average barrier height (ABH) when ferroelectric polarization changes direction, exponentially influencing the tunnelling current.

The ferroelectric insulating layer may be made up of one or more different layers. For instance, the ferroelectric insulating layer may include both a first ferroelectric layer and a graphene layer that are sandwiched together. In addition, a first insulating buffer layer may be disposed between the first ferroelectric layer and the graphene layer. Other configurations are also contemplated, and various different configurations are discussed elsewhere herein. The ferroelectric insulating layer may be a two-dimensional van der Waals material.

Various material compositions are also contemplated. In some embodiments, the first ferroelectric layer may be a bulk ferroelectric material and the first ferroelectric insulating buffer layer may be monolayer hexagonal boron nitride. The first ferroelectric layer may be a bulk ferroelectric material and wherein the first ferroelectric insulating buffer layer may be multilayer hexagonal boron nitride. The bulk ferroelectric material may be at least one of HfO₂ and Hf_{0.5}Zr_{0.5}O₂. The first ferroelectric layer may be a perovskite-based ferroelectric material. The first ferroelectric insulating layer may be CuInP₂S₆. The first ferroelectric insulating layer may be α-In₂Se₃.

In various embodiments, a device includes a first contact made of graphene and a second contact made of chromium, the first contact and the second contact forming asymmetric electrodes. A first ferroelectric layer is provided. The first ferroelectric layer may include CuInP₂S₆ and a graphene layer including monolayer graphene disposed between the first contact and the second contact. The first ferroelectric layer may also include a first insulating buffer layer disposed between the first ferroelectric layer and the graphene layer, wherein the first insulating buffer layer includes hexagonal boron nitride.

In various embodiments, a device includes a pair of asymmetric electrodes, each electrode of the pair of asymmetric electrodes being of a different material. The device includes a ferroelectric insulating layer disposed between the pair of asymmetric electrodes and providing a ferroelectric tunnel junction. A change of direction of ferroelectric polarization causes a large modulation of average barrier height of the ferroelectric insulating layer between the pair of asymmetric electrodes.

### BRIEF DESCRIPTION OF THE DRAWINGS

Other systems, methods, features, and advantages of the present invention will be or will become apparent to one of ordinary skill in the art upon examination of the following figures and detailed description.

FIG. 1 illustrates a diagram of a device having a ferroelectric tunnel junction, in accordance with various embodiments;

FIG. 2 depicts a scanning transmission electron microscopy (STEM) image and an electron energy loss spectroscopy (EELS) image, in accordance with various embodiments;

FIG. 3 illustrates a piezoelectric force microscopy (PFM) image, in accordance with various embodiments;

FIG. 4 illustrates capacitance-voltage measurements, in accordance with various embodiments;

FIG. 5 depicts a graph of tunnelling resistances of a junction plotted as a function of switching voltage pulses applied to change the ferroelectric polarization, in accordance with various embodiments;

FIG. 6 depicts a chart of I-V characteristics of a device, in accordance with various embodiments;

FIG. 7 depicts band diagrams of on and off states, in accordance with various embodiments;

FIG. 8 depicts a graph of I-V characteristics of both on and off states at different temperatures, in accordance with various embodiments;

FIG. 9 depicts Raman spectra, in accordance with various embodiments;

FIG. 10 illustrates surface potential images, in accordance with various embodiments;

FIG. 11 depicts a graph of I-V characteristics of a graphene/CIPS/CR ferroelectric heterostructure, in accordance with various embodiments;

FIG. 12 depicts a graph of the I-V characteristics of an Au/CIPS/CR heterostructure, in accordance with various embodiments;

FIG. 13 shows a graph of current relative to voltage with different graphene contact thicknesses, in accordance with various embodiments;

FIG. 14 depicts a graph of TER relative to number of graphene layers, in accordance with various embodiments;

FIG. 15 illustrates a graph of the resistance of a typical 1LG/CIPS/Cr vdW FTJ as a function of the switching pulse width for write and erase operations, in accordance with various embodiments;

FIG. 16 depicts a graph that characterizes the data retention of a CIPS vdW FTJ, measured at room temperature, in accordance with various embodiments;

FIG. 17 depicts endurance measurements on an vdW FTJ over 5,000 cycles, in accordance with various embodiments;

FIG. 18 shows a chart of resistances of the on and off states of multiple FTJ and corresponding TERs, in accordance with various embodiments;

FIG. 19 illustrates a two-terminal vertical heterostructure device with a first contact that is a metal electrode and a second contact that is a metal electrode with a ferroelectric insulating layer made of a ferroelectric material, in accordance with various embodiments;

FIG. 20 illustrates a two-terminal vertical heterostructure device with a first contact that is a metal electrode and a second contact that is a semi-metal electrode with a ferroelectric insulating layer that is made of a ferroelectric material, in accordance with various embodiments; and

FIG. 21 illustrates a two-terminal vertical heterostructure device with a first contact that is a metal electrode and a second contact that is a graphene electrode with a ferroelectric insulating layer that is a VDW ferroelectric material, in accordance with various embodiments.

### DETAILED DESCRIPTION

There are critical needs for novel high-speed low power non-volatile memory for the next generation electronic memory and computing technology. A ferroelectric tunnel junction (FTJ) is a two-terminal vertical heterostructure that can switch between two or more conductance states in a reversible and non-volatile manner. A ferroelectric tunnel junction (FTJ) having two electrodes separated by a thin ferroelectric (FE) insulating layer is a promising candidate with the potential to replace existing volatile and non-volatile memory. Through the application of electrical pulses, the electrical resistance of a FTJ can be reversibly changed in a non-volatile manner by switching the ferroelectric polarization in the ferroelectric insulator layer.

The ratio between the electrical resistance in a FTJ between the off and on states is known as the tunnelling electroresistance (TER). Achieving a high TER is the critical challenge for obtaining high performance FTJ memory. Described herein is a new device structure and mechanism for obtaining high TER in FTJ devices by inducing high barrier height modulation. In a described novel FTJ structure, the device has one semi-metallic contact (graphene) and another metal contact to form a pair of asymmetric electrodes. Large Fermi level shifts in the semi-metal graphene contact can be achieved with the polarization switching, leading to huge changes in the average barrier height between the on and off states of the FTJ. Due to the low density of states and small quantum capacitance near the Dirac point, the Fermi level shift in the graphene contact can easily reach ˜1 eV even with a relatively small remnant polarization (˜8 μC/cm²). This new metal/FE/semi-metal FTJ structure can be used with any type of ferroelectric materials while the TER performance may be the most optimal when there is weak coupling between the ferroelectric insulator layer and the semi-metallic contact. In the case there is strong coupling at this interface, such as the presence of covalent or ionic bonds, the modulation effect on the barrier height may be reduced.

There are at least two approaches to obtain such weak interactions and hence achieve optimal TER. The first is by employing the van der Waals (vdW) layered ferroelectric materials, such as CuInP₂S₆, to form the vdW FTJs. Due to the self-terminated surface of vdW semimetals like graphene and vdW layered ferroelectric materials, there is typically minimal interface charges, leading to more effective barrier height modulation. Second, for the traditional bulk ferroelectric materials such as doped HfO₂, Hf_{0.5}Zr_{0.5}O₂, and perovskite-based FE materials, it can be beneficial to add an ultra-thin insulating buffer layer between the ferroelectric layer and graphene to ensure a clean interface with minimal interface charges and also to suppress possible leakage. In at least one experimental demonstration, a giant TER (>10⁷) is obtained in the vdW FTJ structure using the layered ferroelectric material CuInP₂S₆ with monolayer graphene and Cr electrodes. This new vdW FTJ also offers high speed and low power operation, and excellent compatibility with silicon CMOS technology. This novel semimetal-contacted FTJ can be extended to devices based on all types of ferroelectric and multiferroic material systems in general that may benefit a wide range of emerging electronic memory and computing applications.

Ferroelectric tunnel junctions use a thin ferroelectric layer as a tunnelling barrier, the height of which can be modified by switching its ferroelectric polarization. The junctions can offer low power consumption, non-volatile switching and non-destructive readout, and thus are promising for the development of memory and computing applications. However, achieving a high tunnelling electroresistance (TER) in these devices remains challenging. Typical junctions, such as those based on barium titanate or hafnium dioxide, are limited by their small barrier height modulation of around 0.1 eV. This disclosure provides a ferroelectric tunnel junction that uses layered copper indium thiophosphate (CuInP₂S₆) as the ferroelectric barrier, and graphene and chromium as asymmetric contacts. The ferroelectric field effect in CuInP₂S₆ can induce a barrier height modulation of 1 eV in the junction, which results in a TER of above 10⁷. This modulation, which is shown using Kelvin probe force microscopy and Raman spectroscopy, is due to the low density of states and small quantum capacitance near the Dirac point of the semi-metallic graphene.

In FTJs, an ultra-thin ferroelectric layer is used as the tunnelling barrier and its average barrier height (ABH) can be modified by switching the ferroelectric polarization. The change in the electrical conductance of the junction due to this polarization reversal results in its tunnelling electroresistance (TER). There are two main types of ferroelectric material used in FTJs: ABO-type perovskites, such as BaTiO₃ (BTO) and PbZr_{0.2}Ti_{0.8}O₃, and binary oxides, such as HfO₂ and Hf_{0.5}Zr_{0.5}O₂ (HZO). In FTJs based on ABO-type perovskites, the TER can reach values of around 10⁶, although this requires incorporation of an additional semiconducting layer in a complex structure in which barrier height and width are both modulated by the polarization field. The ferroelectric materials also have to be grown on a perovskite-based substrate, which limits compatibility with existing electronics technology. FTJs based on binary oxides often have TER values below 100 due to the limitations of the FTJ modulation mechanism and intrinsic material properties. Importantly, the TER in both types of FTJ structure is constrained by the relatively small modulation of the tunnelling barrier height, which is typically below 0.1 eV with either metallic or semiconducting contacts.

As disclosed herein, ferroelectric properties have been observed in two-dimensional (2D) van der Waals (vdW) materials such as CuInP₂S₆ (CIPS) and α-In₂Se₃. The transition temperatures of these materials are well above room temperature and the materials are compatible with industrial silicon electronics processes. In various embodiments, FTJs are provided based on a 2D vdW heterostructure in which CIPS is used as the ferroelectric tunnelling barrier layer and chromium and monolayer graphene (1LG) are used as asymmetric electrodes. Such FTJs exhibit a giant TER of above 10⁷. This behavior may be associated with a large change of the ABH, which results from the large Fermi level shift in graphene spontaneously induced by the polarization field in the adjacent CIPS. Owing to the low density of states in graphene near its Dirac point and its small quantum capacitance, this Fermi level shift can approach 1 eV.

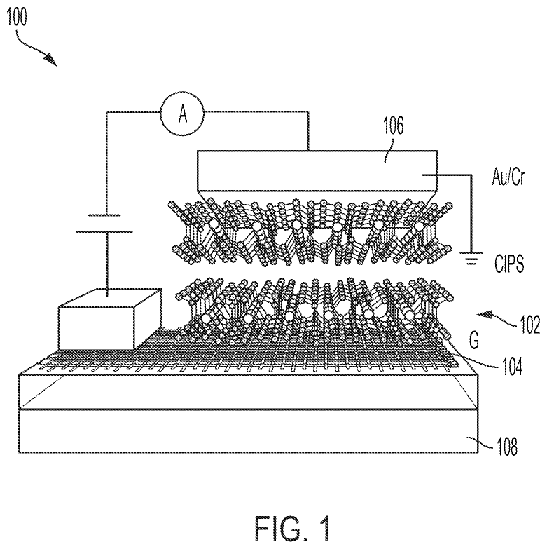

With reference now to FIG. 1, a schematic diagram of a device 100 illustrates the vdW FTJ, where the layered CIPS is used as the ferroelectric insulating layer 102 (e.g., ferroelectric tunnelling barrier layer), and graphene and Cr are used as the asymmetric electrodes. A first electrode 104 of graphene and a second electrode 106 of Cr are illustrated on opposite sides of the ferroelectric insulating layer 102. The Cr/CIPS/graphene FTJ is shown on a SiO₂/Si substrate 108.

In various embodiments, the device 100 includes a first contact 104 and a second contact 106. The first contact 104 may be made of a semi-metallic material, such as graphene. The graphene may be monolayer graphene. The second contact may be made of a metal material, such as chromium (Cr). Thus, the first contact 104 and the second contact 106 may form asymmetric electrodes. A ferroelectric insulating layer 102 is disposed between the first contact 104 and the second contact 106 and is electrically connected to the first contact 104 and to the second contact 106. The asymmetric electrodes may cause a large modulation of average barrier height (ABH) when ferroelectric polarization changes direction, exponentially influencing the tunnelling current.

The ferroelectric insulating layer 102 may be made up of one or more different layers. For instance, the ferroelectric insulating layer 102 may include both a first ferroelectric layer and a graphene layer that are sandwiched together. In addition, a first insulating buffer layer may be disposed between the first ferroelectric layer and the graphene layer. Other configurations are also contemplated, and various different configurations are discussed elsewhere herein. The ferroelectric insulating layer 102 may be a two-dimensional van der Waals material.

Various material compositions are also contemplated. In some embodiments, the first ferroelectric layer may be a bulk ferroelectric material and the first ferroelectric insulating buffer layer may be monolayer hexagonal boron nitride. The first ferroelectric layer may be a bulk ferroelectric material and the first ferroelectric insulating buffer layer may be multilayer hexagonal boron nitride. The bulk ferroelectric material may be at least one of HfO₂ and Hf_{0.5}Zr_{0.5}O₂. The first ferroelectric layer may be a perovskite-based ferroelectric material. The first ferroelectric insulating layer may be CuInP₂S₆. The first ferroelectric insulating layer may be α-In₂Se₃.

In various embodiments, a device 100 includes a first contact 104 made of graphene and a second contact 106 made of chromium, the first contact 104 and the second contact 106 forming asymmetric electrodes. A first ferroelectric layer 102 is provided. The first ferroelectric layer 102 may comprise CuInP₂S₆ and a graphene layer comprising monolayer graphene disposed between the first contact 104 and the second contact 106. The first ferroelectric layer 102 may also comprise a first insulating buffer layer disposed between the first ferroelectric layer and the graphene layer. The first insulating buffer layer may be hexagonal boron nitride.

In various embodiments, a device 100 includes a pair of asymmetric electrodes 104, 106, each electrode 104, 106 of the pair of asymmetric electrodes being of a different material. The device includes a ferroelectric insulating layer 102 disposed between the pair of asymmetric electrodes 104, 106 and providing a ferroelectric tunnel junction. A change of direction of ferroelectric polarization causes a large modulation of average barrier height of the ferroelectric insulating layer between the pair of asymmetric electrodes.

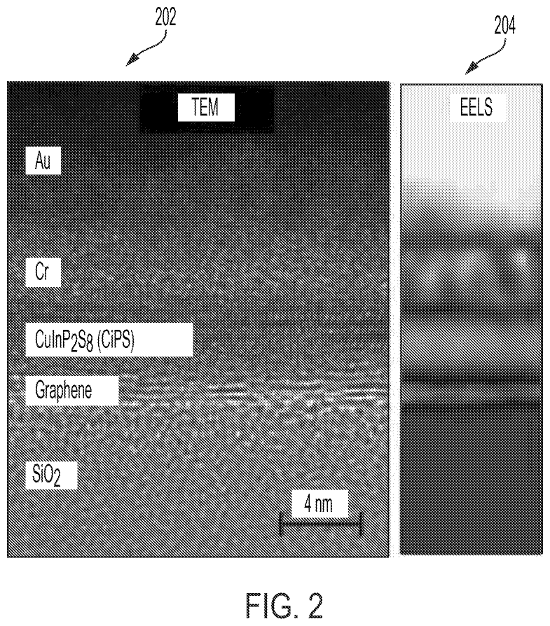

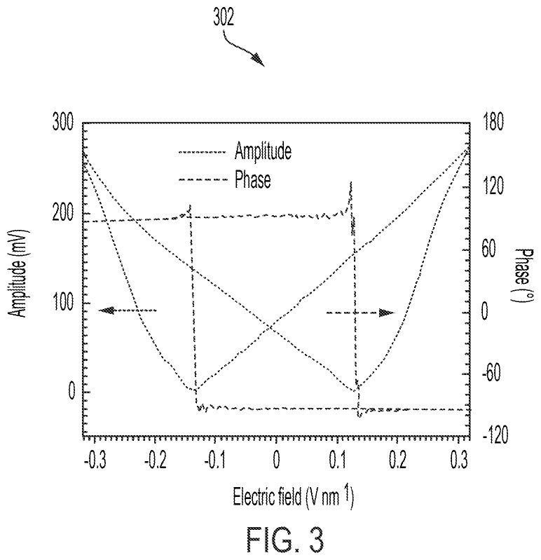

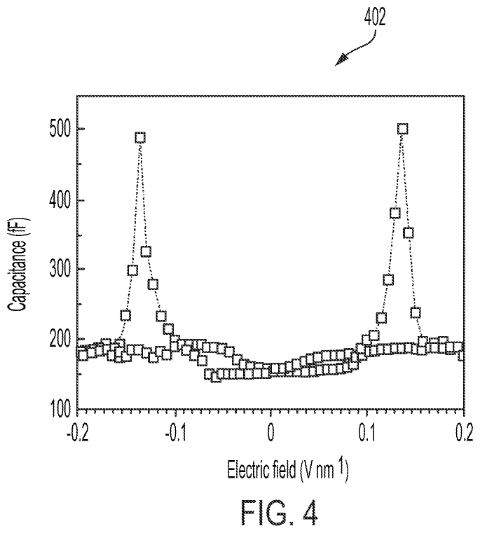

FIG. 2 depicts a scanning transmission electron microscopy (STEM) image 202 and an electron energy loss spectroscopy (EELS) image 204. The images 202, 204 in FIG. 2 show the material compositions in the Cr/CIPS/graphene layered heterostructure. To characterize the ferroelectric properties in the CIPS material, piezoelectric force microscopy (PFM) and capacitance-voltage (C-V) measurements were performed in the metal-CIPS-metal (Au/CIPS/Cr) structure, as shown in FIGS. 3-4. For the PFM measurements 302 in FIG. 3, both the amplitude and phase of the piezoelectric response show hysteresis loops, indicating the existence of ferroelectricity. FIG. 3 depicts out-of-plane amplitude and phase measurements obtained by PFM on an Au/CIPS/Cr test structure. For the C-V characteristics 402 shown in FIG. 4, hysteresis is evident in the butterfly shape with a coercive field of ˜0.14 V nm⁻¹, consistent with the PFM measurement. FIG. 4 depicts capacitance-electric field characteristics obtained using capacitance-voltage (C-V) measurement on an Au/CIPS/Cr test structure. The CIPS sample is 20 nm thick in both FIGS. 3 and 4 scenarios and the measurements were carried out at ˜300 kHz at room temperature. The ferroelectricity of the CIPS at room temperature is thus verified. Moreover, by integrating the C-V characteristics, the remnant polarization (Pr) of this CIPS sample is obtained as ˜8 μC cm⁻².

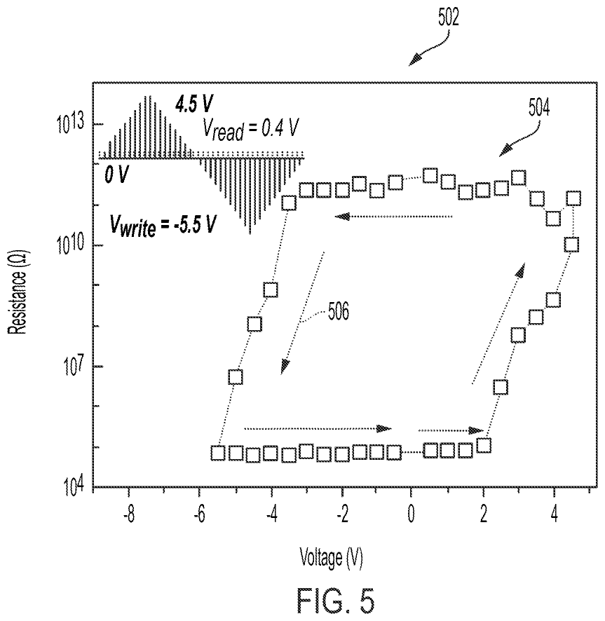

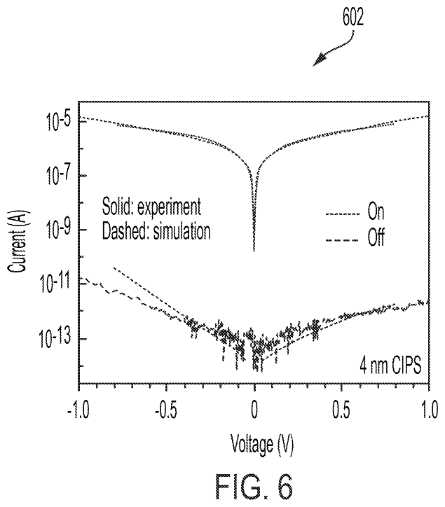

The electrical characteristics of a typical Cr/CIPS/graphene vdW FTJ are shown in FIGS. 5-6 for a device with a 4-nm-thick CIPS layer and a 1LG bottom contact. In FIG. 5, a graph 502 depicts corresponding tunnelling resistances of the junction plotted as a function of the switching voltage pulses applied to change the ferroelectric polarization within the CIPS layer. The hysteresis loops move counterclockwise as a function of the applied voltage pulse train, as illustrated in the inset 504. The arrows 506 indicate the resistances measured using a 0.4 V probing voltage as the switching voltage pulses change from 0 V to 4.5 V, 4.5 V to 0 V, 0 V to −5.5 V and finally back to 0 V. The switching voltages (4 nm CIPS) are consistent with the PFM measurement performed at the same frequency.

FIG. 6 shows a chart 602 of I-V characteristics of the device. The high- and low-resistance states are separately set by voltage pulses of 4.5 V and −5.5 V, respectively, to obtain the corresponding I-V characteristics. A large TER above 10⁷ is obtained in this Cr/CIPS/graphene structure at a bias voltage ˜1 V. When obtaining the I-V characteristics of each state, the voltage sweeps within a relatively small range (from −1 to 1 V) to avoid flipping the direction of the ferroelectric polarization in the CIPS during the measurement. The tunnelling current is low (˜10⁻¹² A) in the off state and sufficiently high (10⁻⁵ A) during the on state in this heterostructure, with a TER above 10⁷. This is at least an order of magnitude above the TER (106) previously reported in ABO-type perovskite FTJs. The dashed lines shows the non-equilibrium Green's function (NEGF) simulation results of the device characteristics, which are consistent with the experimental measurements.

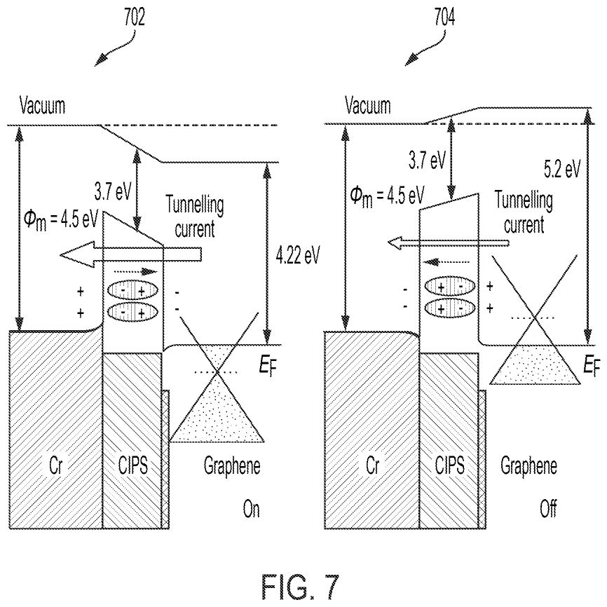

To understand the results, quantum transport simulations based on the non-equilibrium Green's function (NEGF) formalism were performed to calculate the I-V characteristics, as shown by the dashed lines in FIG. 6. The device simulation results indicate that the large TER ratio can be attributed to the efficient modulation of the Fermi level in the graphene contact by the ferroelectric polarization field, and the large effective mass in the vertical direction of the vdW CIPS layer. In contrast to a metal or heavily-doped semiconductor contact, a 1LG contact has a low quantum capacitance near its Dirac point, which results in highly efficient modulation of the contact barrier height. By using a graphene contact and a metal contact in the FTJ, as shown in FIG. 1, asymmetry of the two contact interfaces can lead to a large modulation of the ABH when the ferroelectric polarization switches its direction, which exponentially influences the tunnelling current. Band diagrams 702, 704 of the on and off states are shown schematically in FIG. 7. A band diagram 702 illustrates the on state and another band diagram 704 illustrates the off state. The built-in polarization electric field within the CIPS tunnelling barrier layer induces charges at both interfaces between the CIPS layer and the Cr and graphene electrodes. For the on state (band diagram 702), the induced charges on the graphene side dopes graphene from relatively intrinsic to n-type and causes the Fermi level to shift from relatively intrinsic to well above the Dirac point, as shown on the left side of FIG. 7. The increasing Fermi level decreases the ABH, resulting in higher probability for the electrons to tunnel through the CIPS, and hence induces larger tunnelling current. On the other hand, during the off state (band diagram 704), the ferroelectric polarization field in the CIPS layer is switched to the opposite direction, which induces positive charges on the graphene and dopes the graphene bottom contact to p-type. Thus, the Fermi level in graphene during the off state decreases from the intrinsic to well below the Dirac point, leading to a significant increase in the ABH, as shown on the right side of FIG. 7. It therefore becomes more difficult for electrons to tunnel through the junction and leads to an ultra-low off-state current (˜10⁻¹² A). Based on the Raman and surface potential measurement (discussed later), the shift in the graphene Fermi level between the on and off states can be as large as 1 eV, leading to the high TER.

Furthermore, a large effective mass in the vertical direction of the layered CIPS material due to weak vdW bonding can increase the TER ratio exponentially. Indeed, according to first-principles calculations, the out-of-plane effective mass of CIPS (˜1.3 m₀, where m₀ is the free electron mass) is about three times of that in the in-plane crystal direction, which is similar to the case in other vdW layered materials, such as black phosphorus and MoS₂. The unique properties of both the 2D graphene and CIPS materials are thus important for achieving the high TER ratio.

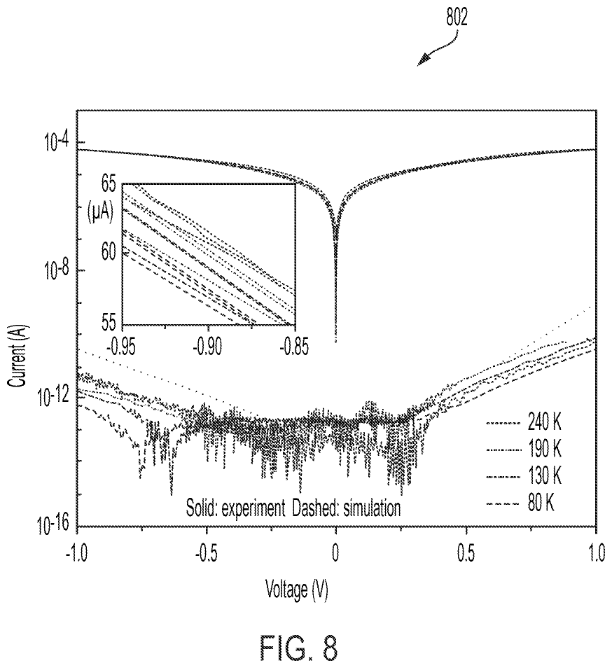

There are three possible transport mechanisms in ultra-thin FTJs: Fowler-Nordheim (FN) tunnelling, direct tunnelling, and thermionic emission. The FN tunnelling usually dominates at large voltage. To verify that the carrier transport mechanism is dominated by direct tunnelling instead of thermionic emission, temperature-dependent I-V measurements were performed, as shown in FIG. 8. FIG. 8 includes a graph 802 of I-V characteristics of both the on and off states at temperatures of 240 K, 190 K, 130 K, and 80 K. The experimental data are shown as solid lines and the NEGF simulation results are shown as dashed lines. For both the on and off states, the I-V characteristics show very weak variations within a large temperature range (from 80 to 240 K). The NEGF simulation results also indicate weak temperature dependence, in agreement with the experimental data. This confirms that the dominant transport mechanism here is direct tunnelling, because, as a thermally activated process, the thermionic emission mechanism would have led to a strong temperature dependence in the I-V characteristics.

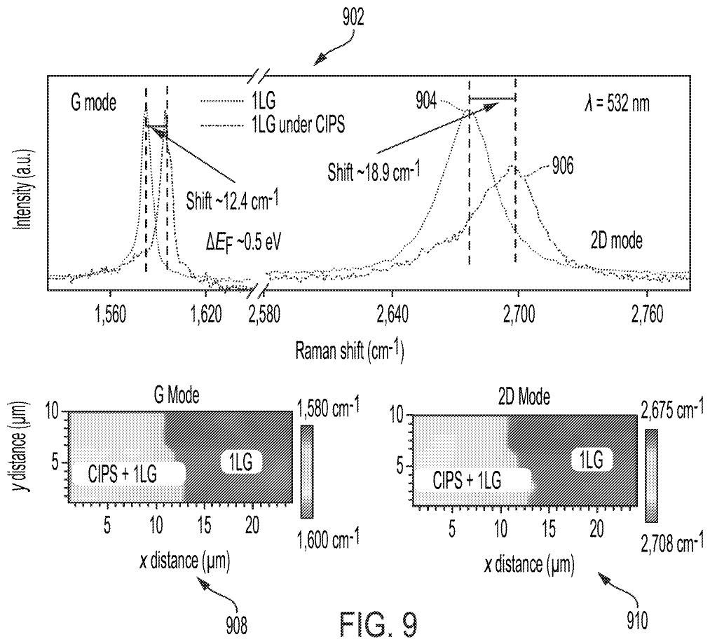

The Fermi-level shift in the graphene contact was first verified using Raman spectroscopy measurements. FIG. 9 shows a Raman spectra 902 of bare 1LG 904 and 1LG under CIPS 906 in the wavelength range of the G and 2D modes under excitation with 532-nm light. The shifts in the Raman peaks and the corresponding Fermi level shift (ΔE_{f}) are indicated. Dashed lines are guides to the eye. FIG. 9 also shows a Raman frequency mapping 908 showing the shift in the G mode of the 1LG and nearby 1LG+CIPS and a Raman frequency mapping 910 showing the shift in the 2D mode of the 1LG and nearby 1LG+CIPS.

As shown in FIG. 9, the G and 2D modes of the 1LG under the CIPS both have blueshifts of more than 12 cm⁻¹ compared to the 1LG region alone. These shifts are attributed to the changes in the doping level of the 1LG due to the effect of the ferroelectric polarization field in the CIPS layer acting on the graphene sheet. Another possible external perturbation that could have led to such large blueshift of both the G and 2D modes in 1LG is the compression strain, which was precluded in this heterostructure through thermal annealing before the measurements to relax the strain. Moreover, the shift in the Fermi level (ΔE_{f}) of the 1LG can be quantitatively given as |ΔE_{f}|≈Δω(G)/21≈0.5 eV, where Δω(G) is the shift in the G-mode peak. As well as the blueshifts in the G and 2D modes, the shift of the Fermi level would result in a decrease in the intensity ratio between the 2D and G modes (I_{2D}/I_{G}), which is also observed in our measurements, further verifying the doping effect. This high doping level is primarily due to the built-in electric field in the CIPS layer acting on the 1LG, rather than from charge transfer between the 1LG and CIPS, which, even if present, can only cause a very small doping effect in 2D heterostructures. Because the Raman peak shift resulting from the doping effects does not distinguish between electron or hole doping, this ΔE_{f} can be either positive or negative depending on whether the Fermi level shifts above or below the Dirac point. Thus, the Fermi level difference for 1LG between the on and off states, based on this estimation, is 2|ΔE_{f}|1 eV.

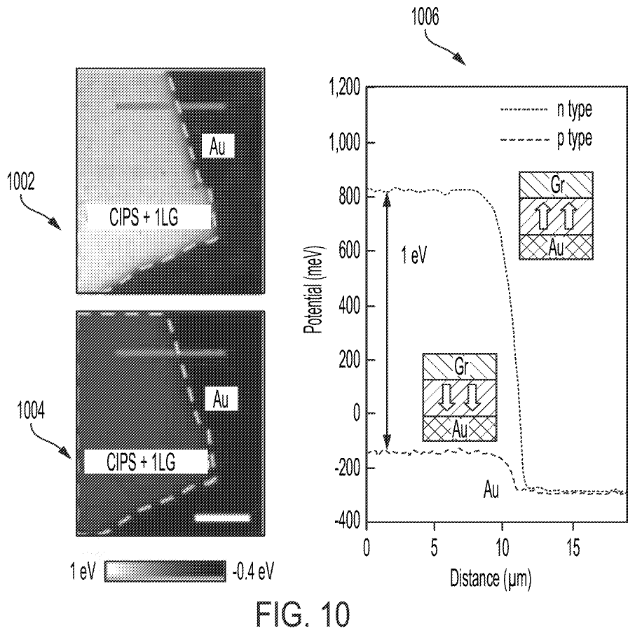

Turning to FIG. 10, to further directly characterize the Fermi-level shift in graphene due to the polarization field switching in CIPS, Kelvin probe force microscopy (KPFM) measurements were used to probe the change in the surface potential, that is, the change in the Fermi level, of the 1LG stacked on the CIPS ferroelectric layer as the polarization in the CIPS layer reverses direction.

FIG. 10 illustrates a surface potential image 1002 of the 1LG stacked on top of CIPS/Au after the ferroelectric polarization in the CIPS layer is set to be pointing upwards (n-type doping in graphene). FIG. 10 also shows a surface potential image 1004 of the 1LG stacked on top of CIPS/Au after the ferroelectric polarization in the CIPS layer is set to be pointing downwards (p-type doping in graphene). FIG. 10 also illustrates a graph 1006 of line plots of the surface potential along the corresponding cuts in the images 1002, 1004.

The polarization in the CIPS layer was deterministically switched by the conductive tip of an atomic force microscopy (AFM) system to change the doping type in the 1LG, which in this case was located on top of the CIPS layer. The surface potential of the p-doped 1LG was ˜0.1 eV higher than that of the gold reference substrate, and the surface potential of the n-doped 1LG was ˜1.1 eV higher than that of the gold reference substrate. This shows that the change in the Fermi level in the 1LG is ˜1 eV due to switching of the ferroelectric polarization in CIPS, consistent with the values extracted from the Raman spectroscopy measurements. This large Fermi-level shift (˜1 eV) is a result of the small density of states and low quantum capacitance in graphene near the Dirac point. Furthermore, numerical simulations of the FTJ device using the NEGF formalism with the effective mass approximation indicate that the Pr of 8 μC cm⁻² is sufficient for a Fermi-level shift of 1 eV. The better coupling observed here compared to ABO-type ferroelectrics coupled with graphene is reasonable due to the all-vdW nature of the graphene/CIPS interface, which is expected to have minimal dangling bonds, surface reconstruction and defect-mediated inter-facial charges.

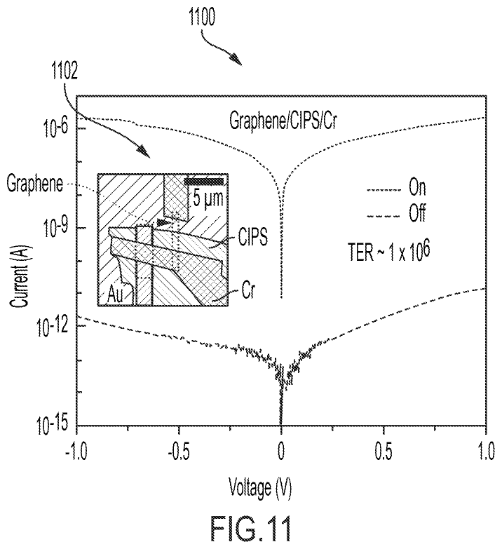

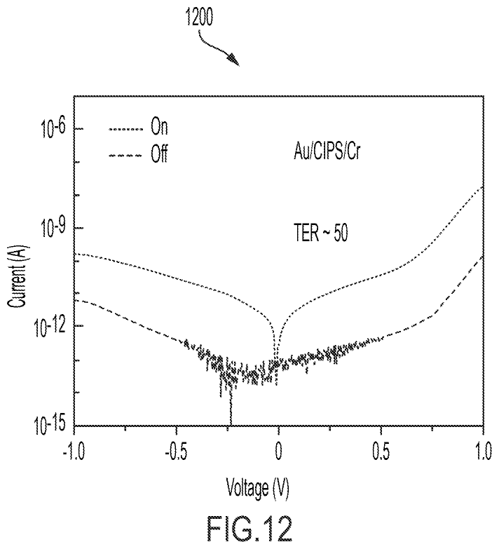

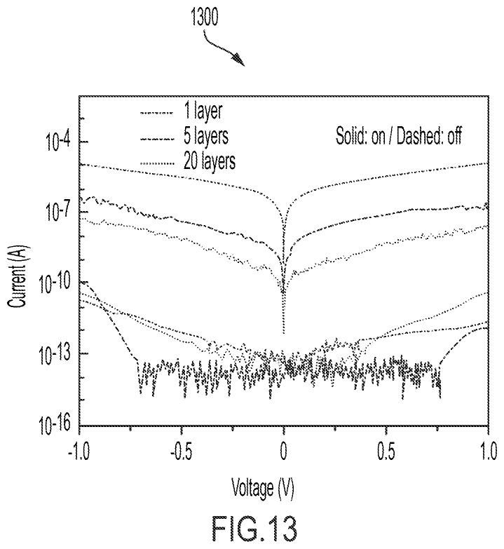

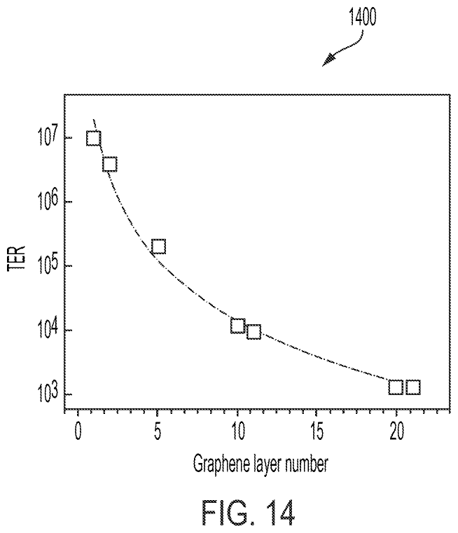

To further verify the effect of the Fermi-level shift in graphene on the TER, both thin graphene (bilayer) and metal (Au) bottom contacts were fabricated, side by side, under the same CIPS sample (thickness of ˜4 nm). The two test structures also share a common top metal electrode (Cr), as shown in the inset 1102 of FIG. 11. FIG. 11 illustrates a graph 1100 of the I-V characteristics of the graphene/CIPS/Cr ferroelectric heterostructure. FIG. 12 illustrates a graph 1200 of the I-V characteristics of the Au/CIPS/Cr heterostructure. The off-state tunnelling currents in both structures are at similar levels in the picoampere regime. However, for the on-state current, the structure with the graphene contact is at the μA level, that is, about four orders of magnitude higher than that in the CIPS structure with metal contacts on both sides. The on-state current of the latter structure is at the nA level. This results in a higher TER (˜10⁶) in the graphene-contacted structure (FIG. 11) compared to the much lower TER (˜50) in the structure with metal contacts on both sides (FIG. 12). FIGS. 13-14 show the dependence of the TER on the graphene contact thickness. Specifically, FIG. 13 shows a graph 1300 of current relative to voltage with different graphene contact thicknesses and FIG. 14 shows a graph 1400 of TER relative to number of graphene layers. As the thickness of the graphene bottom contact is increased from a monolayer up to 21 layers in the vdW FTJs while keeping the CIPS thickness almost constant (˜4 nm), the TER decreases as a result of the increasing screening effect leading to a smaller Fermi-level shift with respect to the increasing graphene contact thickness. This also confirms that the high TER is due to the large Fermi-level shift in the 1LG contact.

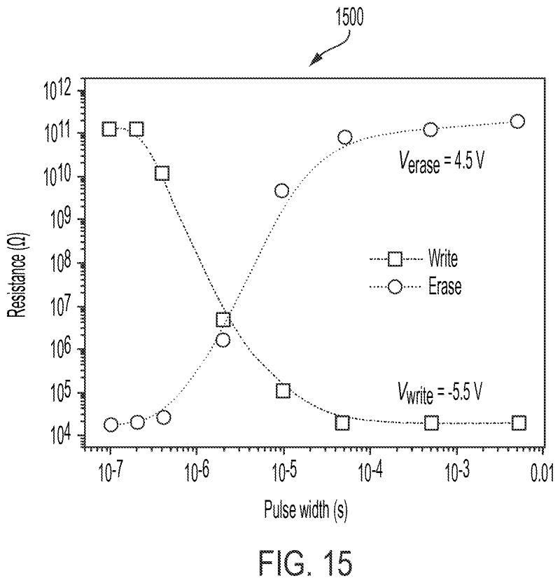

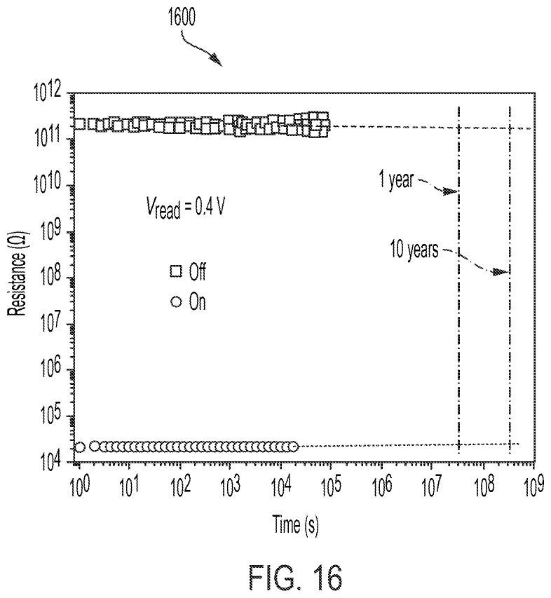

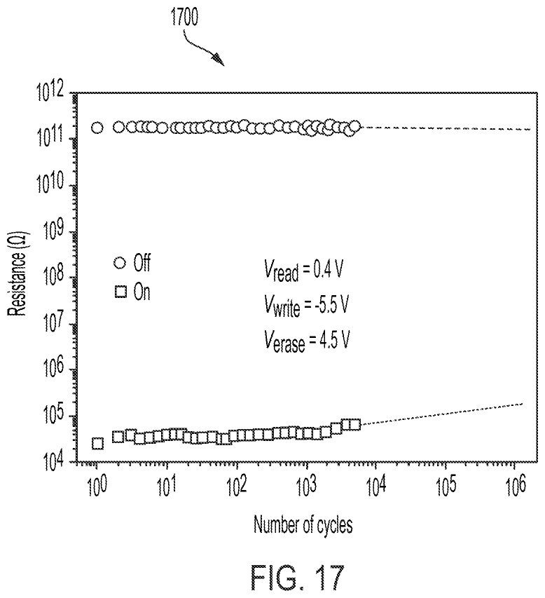

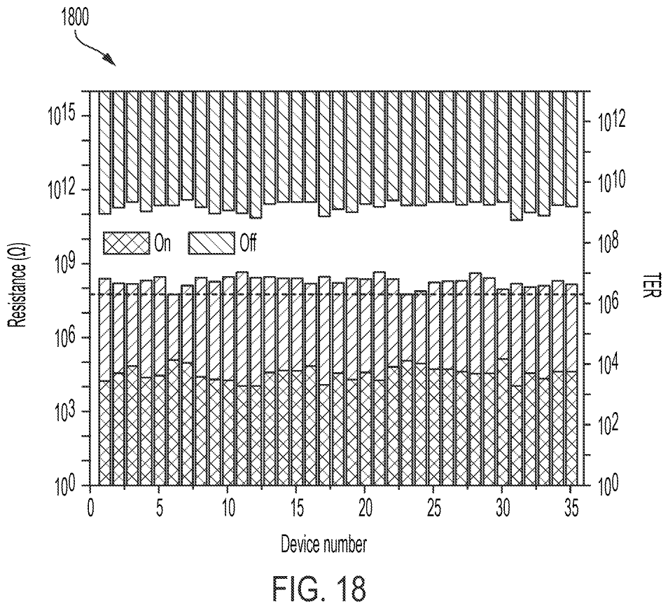

FIG. 15 depicts a graph 1500 illustrating the resistance of a typical 1LG/CIPS/Cr vdW FTJ as a function of the switching pulse width for both the write (off-to-on state) and erase (on-to-off state) operations. The write and erase voltages used are −5.5 V and 4.5 V, respectively. Both the write and erase times are in the range of 10-50 μs, similar to the times for other FTJs reported in the literature with comparable device size. The measured switching time is limited by the parasitics in the device due to the relatively large probe contact pads and device size (2 μm×2 μm). There is significant potential for further improving the switching speed of these devices by removing the probe contact pads and scaling down the device dimensions. FIG. 16 depicts a graph 1600 that characterizes the data retention of this CIPS vdW FTJ, measured at room temperature. The resistance values of the device were measured by first setting the device to the on (off) state and then reading with 0.4 V bias. The TER of the device remained well above 10⁷ after more than 8 h, showing robust performance. FIG. 16 also shows the extrapolation of the data retention based on the experimental results; 1-year and 10-year marks are indicated on the time axis, revealing the great potential of the device for achieving long data retention time. FIG. 17 depicts a graph 1700 that shows the endurance measurement on this vdW FTJ over 5,000 cycles. Within each cycle, the FTJ is set to the on state by a −5.5 V pulse (10 ms) and read at a bias of 0.4 V, then set to the off state using a 4.5 V pulse (10 ms) and read at a bias of 0.4 V. The TER remains well above 106 after 5,000 cycles. Extrapolation based on the experimental data indicates that that the TER can potentially remain above 106 after one million switching cycles. To characterize the device uniformity and potential scalability, a 5×7 vdW FTJ array was fabricated with graphene contacts. FIG. 18 shows a chart 1800 of the resistances of the on and off states of these 35 FTJs and the corresponding TERs, showing good device uniformity.

FTJs based on a graphene/CIPS/Cr vdW hetero-structure offer a high TER of above 10⁷. Unlike FTJs based on ABO-type perovskites, where the highest TER is enhanced by the modulation of the tunnelling barrier width, devices disclosed herein rely on the large modulation of the tunnelling barrier height. Reversal of the ferroelectric polarization field in CIPS causes a Fermi-level shift of ˜1 eV in the graphene contact. The TER is further enhanced by the high carrier effective mass along the out-of-plane crystal direction of the CIPS, and the 4 nm tunnelling barrier is favorable for low-power device operation. A semimetal-ferroelectric vdW structure provides a new approach for achieving high giant barrier height modulation in FTJ devices, which is a critical step towards developing high-performance ferroelectric and multiferroic materials for memory and computing applications.

The CuInP₂S₆ (CIPS) crystals were synthesized using a chemical vapor transport method. Powders of Cu, In, P and S were mixed in stoichiometric proportions (mole ratio of Cu:In:P:S=1:1:2:6, 1 g in total) and flame-sealed in quartz ampoules under vacuum (10-4 torr). The ampoules were loaded into a two-zone furnace and heated to ˜750-680° C. over a period of 12 h with one end of the ampoules enclosing the powders being placed in the 750° C. zone. The reaction was held at ˜750-680° C. for a week and then cooled to room temperature in 24 h. After opening the ampoule, orange platelets embedded in a powder bulk were obtained at the other end of the ampoule (located in the 750° C. zone).

The graphene sheets were mechanically exfoliated on silicon wafers with 285-nm thermally grown SiO₂. The thin CIPS sample (exfoliated onto polydimethylsiloxane) was then transferred onto the graphene sheet on the Si/SiO₂ wafer using a transfer station with micrometer-resolution alignment under an optical microscope. The sample with the graphene/CIPS heterostructure was then soaked in acetone and isopropanol for 30 min each to remove any potential organic residue on the sample surface. Subsequently, the sample was annealed in an Ar/H₂ (20:1) environment at 300° C. to improve the interfacial quality of the heterostructure. Finally, the top electrode was defined using Raith electron-beam lithography (EBL), which was then formed by depositing 5-nm Cr and 40-nm Au using a Kurt J. Lesker metal evaporator.

An FEI Titan Themis G2 system was used to obtain HRSTEM images with four detectors and spherical aberration. The sample was pre-treated by coating with chromium and carbon layers, then thinned by a focused-ion beam (FIB, FEI Helios 450S) with an acceleration voltage of 30 kV. To obtain the HRSTEM image, the acceleration voltage was increased to 200 kV during imaging. EELS signals were collected by a Gatan 977 spectrometer, which was integrated within the STEM system.

The I-V and C-V characteristics were measured using a Keysight B1500A semiconductor device analyzer in a Lakeshore probe station. A cryogenic system was used to measure the temperature-dependent I-V characteristics. C-V measurements were carried out using a Keysight N1301A module at 300-KHz frequency.

The NEGF formalism was used to treat the quantum transport in the CIPS-based FTJ. Transmission coefficients were calculated at different bias voltages with the NEGF approach, and the current was computed with the Landauer-Büttiker formula. To model the electrostatic effect, a capacitance model was developed to treat the shift in the graphene Fermi energy level due to the graphene charge, ferroelectric polarization charge, and metal screening effects.

A Renishaw inVia Qontor system with a ×100 objective lens, a grating (1,800 grooves mm⁻¹) and a charge-coupled device camera was used to measure the Raman spectra of the 1LG and CIPS sample. The CIPS sample was set to be polarized before the measurement using the conductive module in a Bruker Dimension Icon AFM system. The wavelength of the excitation laser was 532 nm (from a solid laser), giving a resolution of 1.2 cm⁻¹ per pixel. To protect the sample, the laser power was kept below 0.1 mW. The integration time was 20 min for each spectrum to obtain a good signal-to-noise ratio.

A Bruker Dimension Icon system was used for PFM and KPFM measurements. A conductive probe (resistivity of 0.01-0.025 Ψcm, SCM-PIT-V2) with an elastic constant of 3 N m⁻¹ was used. For PFM measurements, a resonance frequency of ˜300 kHz was used. For KPFM measurements, the lift mode was used with a lift height of 50 nm. To measure the surface potential of the 1LG, the Au/CIPS/1LG structure was used. Ferroelectric polarization within the CIPS was deterministically switched using the tip bias (−6 and 6 V, respectively) in the conductive mode before the KPFM measurements. The surface potential was calibrated using a standard Al—Au sample from Bruker.

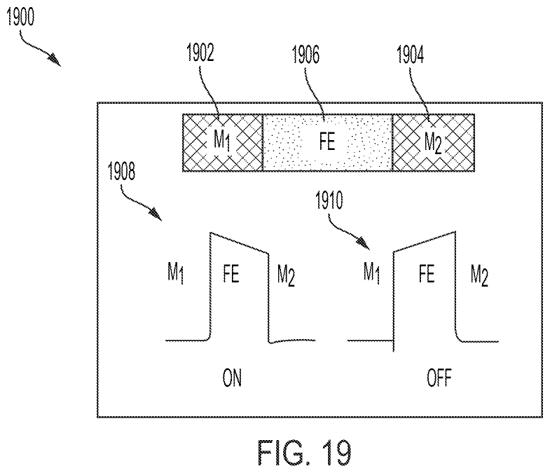

Turning now to FIGS. 19, 20, and 21, various different configurations of ferroelectric tunnel junction (FTJ) devices are shown. For instance, FIG. 19 illustrates a two-terminal vertical heterostructure device 1900 with a first contact 1902 that is a metal electrode and a second contact 1904 that is a metal electrode with a ferroelectric insulating layer 1906 made of a ferroelectric material therebetween that can switch between two or more conductance states in a reversible and non-volatile manner. FIG. 19 shows a band profile 1908 for an ‘on’ conductance state and a band profile 1910 for an ‘off’ conductance state.

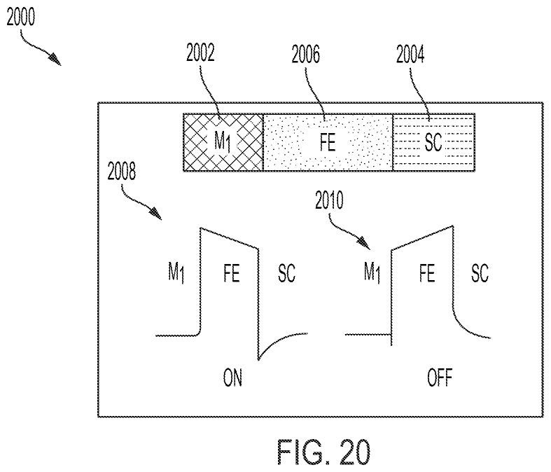

FIG. 20 illustrates a two-terminal vertical heterostructure device 2000 with a first contact 2002 that is a metal electrode and a second contact 2004 that is a semiconductor electrode with a ferroelectric insulating layer 2006 that is a ferroelectric material therebetween that can switch between two or more conductance states in a reversible and non-volatile manner. FIG. 20 shows a band profile 2008 for an ‘on’ conductance state and a band profile 2010 for an ‘off’ conductance state.

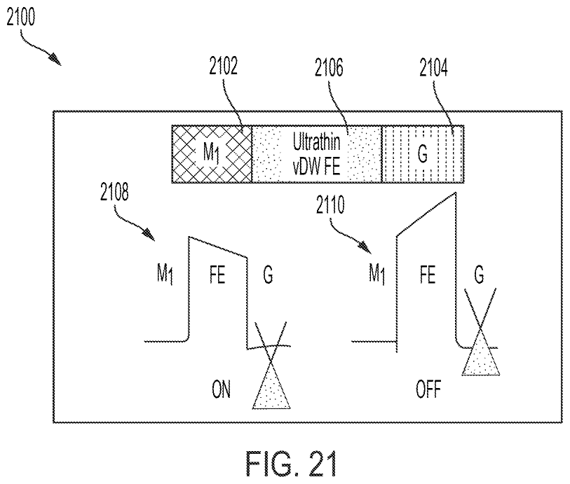

FIG. 21 illustrates a two-terminal vertical heterostructure device 2100 with a first contact 2102 that is a metal electrode 2102 and a second contact 2104 that is a graphene electrode with a ferroelectric insulating layer 2106 that is a VDW ferroelectric material therebetween that can switch between two or more conductance states in a reversible and non-volatile manner. FIG. 21 shows a band profile 2108 for an ‘on’ conductance state and a band profile 2110 for an ‘off’ conductance state.

FIGS. 19-21 depict various different devices having different structures. Table 1 below further details different characteristics of each device.

TABLE 1

| | | | vdW FTJ with |
|---|---|---|---|
| | | FTJ with | metal |
| | Conventional FTJ | metal and | and semi- |
| | with two metal | semiconductor | metal (Graphene) |
| | contacts | contacts | Contacts |
| | (FIG. 19 Device) | (FIG. 20 Device) | (FIG. 21 Device) |
| TER | Low (<10³) | Medium (~10⁵-10⁶) | High (>10⁷) |
| | | for perovskite | |
| | | based; | |
| | | Low (<10²) | |
| | | for HfO₂ | |
| | | based | |
| Switching | Medium | Medium | Fast |
| Energy | Medium | Medium | Low |
| Interface | Very small | Medium | Large |
| Modulabilty | | | |
| FE | ~4 nm for | ~4 nm for | <1 nm |
| Thickness | HfO₂; 1-2 | HfO₂; 1-2 | |
| Scalability | nm for perovskite | nm for perovskite | |
| Data | >10 | >10 | >10 |
| Retention | years | years | years |
| Endurance | High | High | High |

Exemplary embodiments of the invention have been disclosed in an illustrative style. Accordingly, the terminology employed throughout should be read in a non-limiting manner. Although minor modifications to the teachings herein will occur to those well versed in the art, it shall be understood that what is intended to be circumscribed within the scope of the patent warranted hereon are all such embodiments that reasonably fall within the scope of the advancement to the art hereby contributed, and that that scope shall not be restricted, except in light of the appended claims and their equivalents.

What is claimed is:

1. A device comprising:
a first contact made of a semi-metallic material;
a second contact made of a metal material, the first contact and the second contact forming asymmetric electrodes; and
a ferroelectric insulating layer disposed between the first contact and the second contact and electrically connected to the first contact and the second contact.

2. The device of claim 1, wherein the ferroelectric insulating layer comprises a first ferroelectric layer and a graphene layer sandwiched together.

3. The device of claim 2, wherein the ferroelectric insulating layer further comprises a first insulating buffer layer disposed between the first ferroelectric layer and the graphene layer.

4. The device of claim 3, wherein the first ferroelectric layer comprises a bulk ferroelectric material and wherein the first ferroelectric insulating buffer layer comprises monolayer hexagonal boron nitride.

5. The device of claim 3, wherein the first ferroelectric layer comprises a bulk ferroelectric material and wherein the first ferroelectric insulating buffer layer comprises multilayer hexagonal boron nitride.

6. The device of claim 4, wherein the bulk ferroelectric material comprises at least one of HfO₂ and Hf_{0.5}Zr_{0.5}O₂.

7. The device of claim 5, wherein the bulk ferroelectric material comprises at least one of HfO₂ and Hf_{0.5}Zr_{0.5}O₂.

8. The device of claim 3, wherein the first ferroelectric layer comprises a perovskite-based ferroelectric material.

9. The device of claim 1, wherein the first ferroelectric insulating layer comprises CuInP₂S₆.

10. The device of claim 1, wherein the first ferroelectric insulating layer comprises α-In₂Se₃.

11. The device of claim 1, wherein the ferroelectric insulating layer is a two-dimensional van der Waals material.

12. The device of claim 1, wherein the first contact comprises graphene.

13. The device of claim 1, wherein the first contact comprises monolayer graphene.

14. The device of claim 1, wherein the second contact comprises chromium.

15. The device of claim 1, wherein the asymmetric electrodes cause a large modulation of average barrier height (ABH) when ferroelectric polarization changes direction, exponentially influencing the tunnelling current.

16. A device comprising:
a first contact made of graphene;
a second contact made of chromium, the first contact and the second contact forming asymmetric electrodes;
a first ferroelectric layer comprising CuInP₂S₆ and a graphene layer comprising monolayer graphene disposed between the first contact and the second contact.

17. The device of claim 16, further comprising a first insulating buffer layer disposed between the first ferroelectric layer and the graphene layer, wherein the first insulating buffer layer comprises hexagonal boron nitride.

18. A device comprising:
a pair of asymmetric electrodes, each electrode of the pair of asymmetric electrodes being of a different material; and
a ferroelectric insulating layer disposed between the pair of asymmetric electrodes and providing a ferroelectric tunnel junction;
wherein a change of direction of ferroelectric polarization causes a large modulation of average barrier height of the ferroelectric insulating layer between the pair of asymmetric electrodes.

19. The device according to claim 18, wherein the pair of asymmetric electrodes includes a first electrode made of a semi-metallic material and a second electrode made of a metallic material.

20. The device according to claim 19, wherein the ferroelectric insulating layer includes a first ferroelectric layer and a graphene layer.
